(19) United States
(12) Patent Application Publication
(10) Pub. No.: US 2013/0270426 A1
(43) Pub. Date: Oct. 17, 2013

(54) LENS MODULE

(71) Applicants: Ching-Shan Yang, Tainan (TW); Wu-Li Wang, Tainan (TW)

(72) Inventors: Ching-Shan Yang, Tainan (TW); Wu-Li Wang, Tainan (TW)

(73) Assignee: GLOBAL MICROPTICS COMPANY, Tainan (TW)

(21) Appl. No.: 13/446,318

(22) Filed: Apr. 13, 2012

(51) Int. Cl. H01L 31/0232

(52) U.S. Cl. 250/226; 250/216

(57) ABSTRACT

A lens module for transforming optical signals into electrical signals includes an image sensor provided at a tail of an optical axis to transform optical signals into electrical signals; a first lens provided on the image sensor, wherein the first lens has at least a non-flat lens portion; and a second lens provided on the first lens, wherein the second lens has at least a non-flat lens portion.

### BACKGROUND OF THE INVENTION

1. Field of the Invention

The present invention relates generally to an optical device, and more particularly to a lens module.

2. Description of the Related Art

In recent days, image pick-up apparatus, such as digital camera, video camera, microscope, and scanner, are made as smaller and lighter as possible for user to carry and operate in an easy way so that lens modules, which are mounted on the image pick-up apparatus to catch images, are asked as smaller as possible accordingly. Except for the size and weight, optical performance is asked as higher as possible to catch images with high definition and contrast. Therefore, size and optical performance are the important things in the modern lens modules.

As shown in FIG. 1, a conventional lens module 5 includes an image sensor 100, a cover glass 110, and at least a lens 120. The image sensor 100 transforms the optical signals into electrical signals, the cover glass 100 is attached to the image sensor 100 for protection, and the lens 120 is provided on the cover glass 100 to change the character of light.

In the conventional lens module 5 the cover glass 110 does nothing but protects the image sensor 100. However, it increases the thickness of the lens module 5, and furthermore, it may change the optical character of the light emitting therethrough, such as changing the path of light and decreasing the intensity, and that may affect the optical performance of the conventional lens module 5. Therefore, the conventional lens module 5 still has some places to be improved.

### SUMMARY OF THE INVENTION

The primary objective of the present invention is to provide a lens module with small size and high optical performance.

According to the objective of the present invention, a lens module for transforming optical signals into electrical signals includes an image sensor provided at a tail of an optical axis to transform optical signals into electrical signals; a first lens provided on the image sensor, wherein the first lens has at least a non-flat lens portion; and a second lens provided on the first lens, wherein the second lens has at least a non-flat lens portion.

In an embodiment, the lens module further includes an IR cut filter provided on the first lens or on the second lens.

In an embodiment, the IR cut filter is provided on a side of the first lens proximal to the image sensor.

In an embodiment, the first lens has a flat lens portion opposite to the non-flat lens portion and attached to the image sensor.

In an embodiment, the first lens has a lens portion opposite to the non-flat lens portion and a protrusion around the lens portion, whereby the protrusion is attached to the image sensor so that the lens portion keeps a distance away from the image sensor.

In an embodiment, the lens portion within the protrusion is non-flat.

In an embodiment, the second lens further has a non-flat lens portion opposite to the non-flat lens portion.

The present further provides a lens module for transforming optical signals into electrical signals, including an image sensor provided at a tail of an optical axis to transform optical signals into electrical signals; and a lens provided on the image sensor, wherein the lens has at least a convex lens portion.

In an embodiment, the lens has a flat lens portion opposite to the convex lens portion to be attached to the image sensor.

In an embodiment, the lens has a protrusion around the convex lens portion to be attached to the image sensor so that the convex lens portion keeps a distance away from the image sensor.

In an embodiment, the lens has a flat lens portion opposite to the convex lens portion.

In an embodiment, the lens has a non-flat lens portion opposite to the convex lens portion.

In an embodiment, a height of the protrusion is greater than a depth of the recess.

In an embodiment, a depth of the recess is greater than a height of the protrusion.

In an embodiment, an angle between a sidewall of the protrusion of the first lens and a horizontal plane is in a range between 60 degrees and 90 degrees.

In an embodiment, an angle between a sidewall of the protrusion of the first lens and a horizontal plane is in a range between 75 degrees and 85 degrees.

In an embodiment, an angle between a sidewall of the recess of the second lens and a horizontal plane is in a range between 90 degrees and 120 degrees.

In an embodiment, an angle between a sidewall of the recess of the second lens and a horizontal plane is in a range between 95 degrees and 105 degrees.

In an embodiment, the first lens portion of the first lens is concave, and the second lens portion of the second lens is concave.

In an embodiment, the first lens portion of the first lens is convex, and the second lens portion of the second lens is concave.

In an embodiment, the first lens portion of the first lens is concave, and the second lens portion of the second lens is convex.

Therefore, the engagement of the protrusion and the recess may fix the first and the second lenses before the glue solidified in an easy and accurate way.

### BRIEF DESCRIPTION OF THE DRAWINGS

FIG. 1 is a sketch diagram of the conventional lens module;

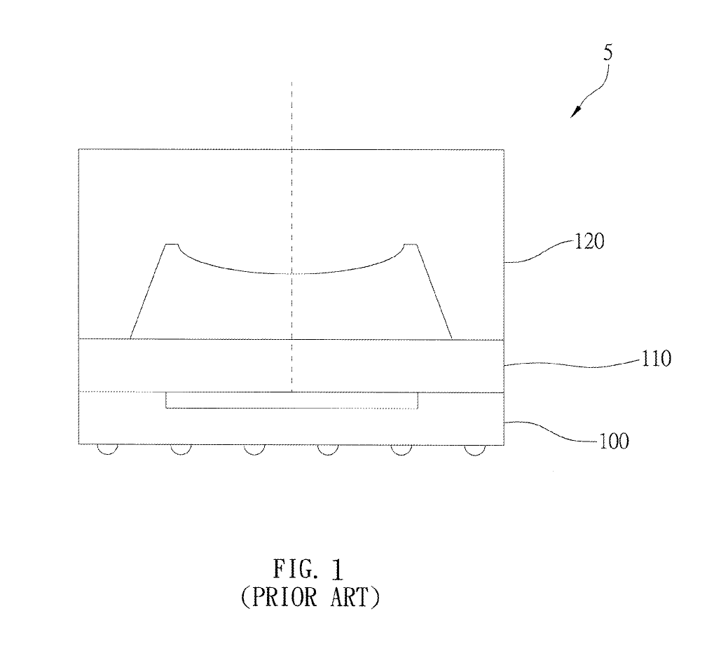

FIG. 2 is a sketch diagram of a first preferred embodiment of the present invention;

FIG. 3 is a sketch diagram of a second preferred embodiment of the present invention;

FIG. 4 is a sketch diagram of a third preferred embodiment of the present invention; and

FIG. 5 is a sketch diagram of a fourth preferred embodiment of the present invention.

### DETAILED DESCRIPTION OF THE INVENTION

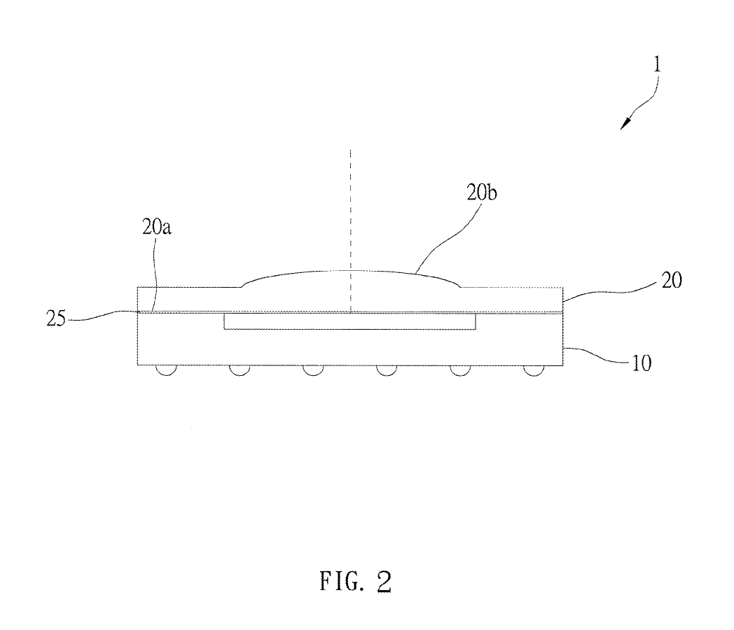

As shown in FIG. 2, a lens module 1 of the first preferred embodiment of the present invention includes an image sensor and a lens 20.

The image sensor 10 is provided at a tail of an optical axis to transform optical signals into electrical signals. The image sensor 10 may be complementary metal oxide semiconductor (CMOS), charge coupled device (CCD), or other equivalent devices.

The lens 20 is on the optical axis and covers the image sensor 10. The lens 20 has a first lens portion 20a attached to the image sensor 10 and a second lens portion 20b opposite to the first lens portion 20a. The first lens portion 20a is flat, and the second lens portion 20b is convex.

The lens 20 provides both functions of changing light character and protecting the image sensor 10, in other words, the first lens portion 20a changes light character, and the lens 20 is attached to the image sensor 10 to protect it. An IR cut filter 25 is provided on the first lens portion 20a of the lens 20 to filter infrared rays out that may increase the optical performance of the lens module 1.

In conclusion, it is obvious that no cover glass is needed in the lens module 1 of the present invention because the lens 20 serves both functions of protecting image sensor 10 and changing light character. With the filter 25 and the convex second lens portion 20b the lens module 1 of the present invention has a small size and a high optical performance.

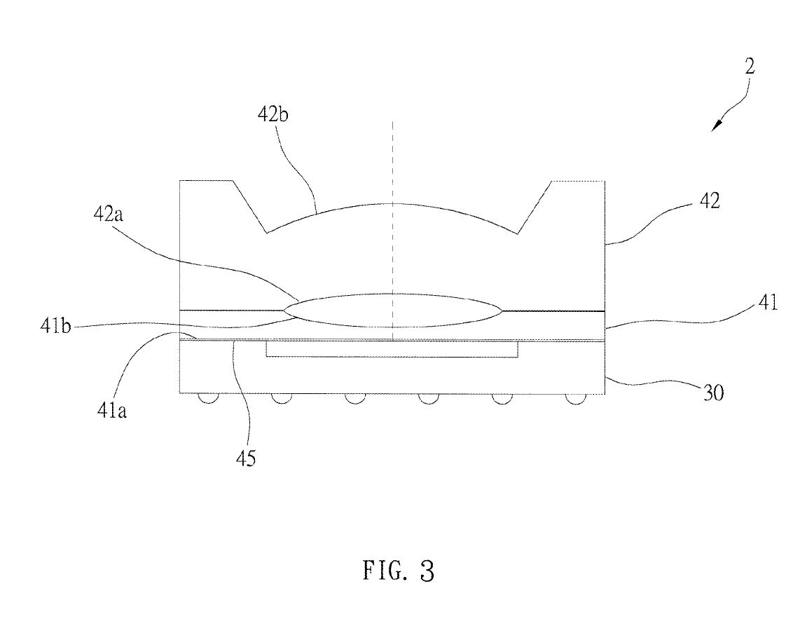

Except for the structure disclosed as above, it may provide two or more lenses to serve the same function. As shown in FIG. 3, a lens module 2 of the second preferred embodiment of the present invention includes an image sensor 30, a first lens 41, and a second lens 42.

The image sensor 30 is provided at a tail of an optical axis to transform optical signals into electrical signals.

The first lens 41 is on the optical axis and is provided on the image sensor 30. The first lens 41 has a flat first lens portion 41a attached to the image sensor 30 and a concave second lens portion 41b opposite to the first lens portion 41a. An IR cut filter 45 is provided on the first lens portion 41a of the first lens 41.

The second lens 42 is on the optical axis also and is next to the first lens 41. The second lens 42 has a concave first lens portion 42a facing the second lens portion 41b of the first lens 41 and a convex second lens portion 42b opposite to the first lens portion 42a. The character of the first and the second lens portions 42a, 42b of the second lens 42 are based on the optical requirements of the lens module 2 so that the first and the second lens portions 42a, 42b of the second lens 42 may be convex, concave, or flat.

The lens module 2 of the second preferred embodiment provides the first lens 41 to server both functions of protecting the image sensor 30 and changing light character so that no cover glass is needed in the lens module 2. The second lens 42 and the filter 45 work with the first lens 41 to increase the optical performance of the lens module 2.

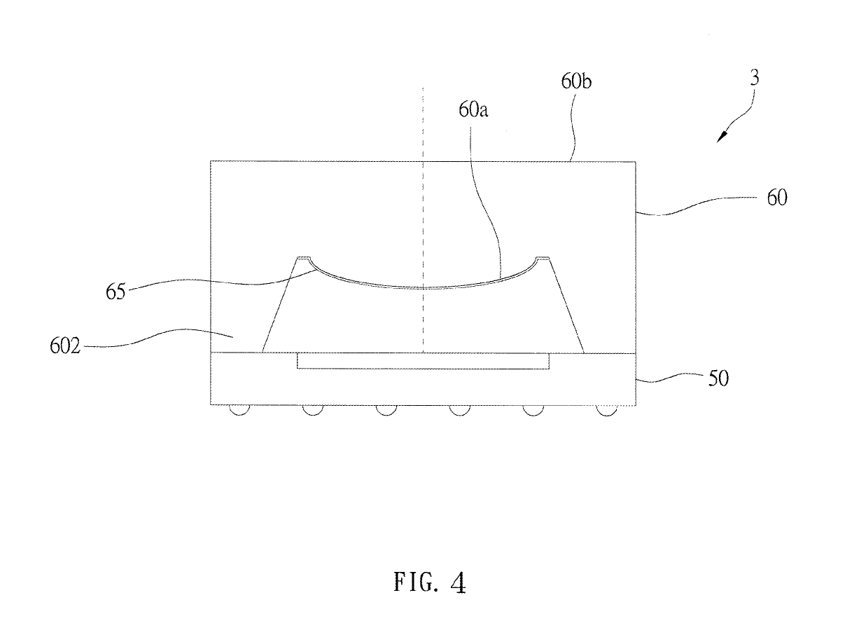

The lens for protecting the image sensor may be not fully attached to the image sensor. As shown in FIG. 4, a lens module 3 of the first preferred embodiment of the present invention includes an image 50 and a lens 60.

The image sensor 50 is provided at a tail of an optical axis to transform optical signals into electrical signals.

The lens 60 is on the optical axis and is above the image sensor 50. The lens 60 has a convex first lens portion 60a and an annular protrusion 602 around the first lens portion 60a. The lens 60 is provided on the image sensor 50 by attaching the protrusion 602 to the image sensor 50 so that the first lens portion 60a is kept a distance away from the image sensor 50. The lens 60 further has a flat second lens portion 60b opposite to the first lens portion 60a, and an IR cut filter 65 on the first lens portion 60a. The same as above, the first and second lens portions 60a, 60b may be flat, convex, or concave based on the optical requirements.

The lens 60 of the present embodiment serves both functions of protecting image sensor 10 and changing light character, and the first lens portion 60a may not be flat to enhance the optical function.

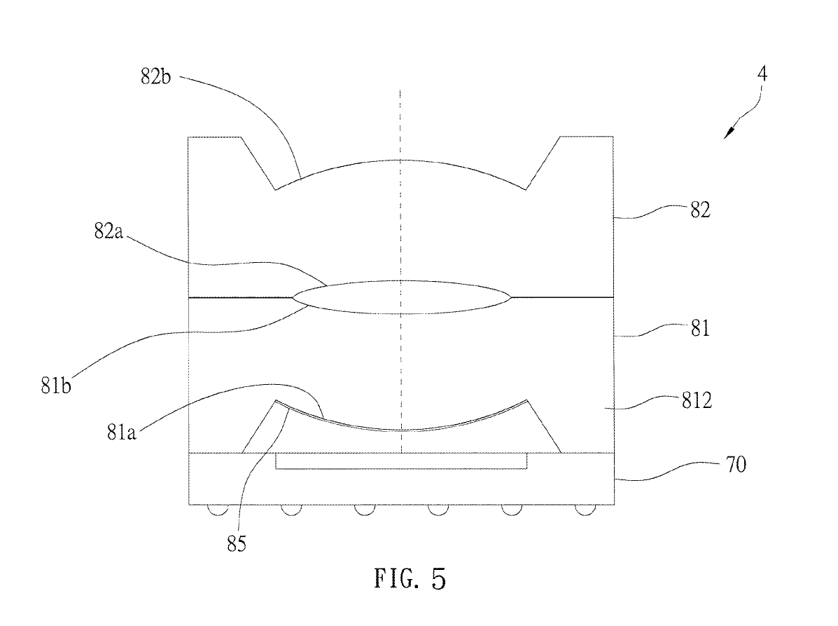

The idea of the third embodiment may be achieved by two or more lenses as well. As shown in FIG. 5, a lens module 4 of the fourth preferred embodiment of the present invention includes an image sensor 70, a first lens 81, and a second lens 82.

The image sensor 70 is provided at a tail of an optical axis to transform optical signals into electrical signals.

The first lens 81 is on the optical axis and is above the image sensor 30. The first lens 81 has a convex first lens portion 81a and an annular protrusion 812 around the first lens portion 81a. The first lens 81 is provided on the image sensor 70 by attaching the protrusion 812 to the image sensor 70 so that the first lens portion 81a is kept a distance away from the image sensor 70. The first lens 81 further has a concave second lens portion 81b opposite to the first lens portion 81a, and an IR cut filter 85 on the first lens portion 81a. The same as above, the first and second lens portions 81a, 81b may be flat, convex, or concave based on the optical requirements.

The second lens 82 is on the optical axis also and next to the first lens 81. The second lens 82 has a concave first lens portion 82a facing the second lens portion 81b of the first lens 81 and a convex second lens portion 82b opposite to the first lens portion 42a. The same as above, the first and the second lens portions 82a, 82b may be convex, concave, or flat based on the optical requirement.

The lens module 4 of the fourth preferred embodiment provides the first lens 81 to server both functions of protecting the image sensor 70 and changing light character so that no cover glass is needed in the lens module 4. The second lens 82 and the filter 85 work with the first lens 81 to increase the optical performance of the lens module 4.

In above embodiment the IR cut filter is provided on the side of the lens closest to the image sensor. It is easy to understand that the IR cut filter may be provided on any side of the lenses. The description above is a few preferred embodiments of the present invention and the equivalence of the present invention is still in the scope of claim construction of the present invention.

What is claimed is:

1. A lens module for transforming optical signals into electrical signals, comprising:
an image sensor provided at a tail of an optical axis to transform optical signals into electrical signals;
a first lens provided on the image sensor, wherein the first lens has at least a non-flat lens portion; and
a second lens provided on the first lens, wherein the second lens has at least a non-flat lens portion.

2. The lens module as defined in claim 1, further comprising an IR cut filter provided on the first lens or on the second lens.

3. The lens module as defined in claim 2, wherein the IR cut filter is provided on a side of the first lens proximal to the image sensor.

4. The lens module as defined in claim 1, wherein the first lens has a flat lens portion opposite to the non-flat lens portion and attached to the image sensor.

5. The lens module as defined in claim 1, wherein the first lens has a lens portion opposite to the non-flat lens portion and a protrusion around the lens portion, whereby the protrusion is attached to the image sensor so that the lens portion keeps a distance away from the image sensor.

6. The lens module as defined in claim 5, wherein the lens portion within the protrusion is non-flat.

7. The lens module as defined in claim 1, wherein the second lens further has a non-flat lens portion opposite to the non-flat lens portion.

8. A lens module for transforming optical signals into electrical signals, comprising:
an image sensor provided at a tail of an optical axis to transform optical signals into electrical signals; and
a lens provided on the image sensor, wherein the lens has at least a convex lens portion.

9. The lens module as defined in claim 8, wherein the lens has a flat lens portion opposite to the convex lens portion to be attached to the image sensor.

10. The lens module as defined in claim 8, wherein the lens has a protrusion around the convex lens portion to be attached to the image sensor so that the convex lens portion keeps a distance away from the image sensor.

11. The lens module as defined in claim 10, wherein the lens has a flat lens portion opposite to the convex lens portion.

12. The lens module as defined in claim 10, wherein the lens has a non-flat lens portion opposite to the convex lens portion.
